(19) United States
(12) Patent Application Publication
(10) Pub. No.: US 2011/0088769 A1
(43) Pub. Date: Apr. 21, 2011

(54) PROCESS OF FORMING AN ELECTRODE ON THE FRONT-SIDE OF A NON-TEXTURED SILICON WAFER

(75) Inventors: Kenneth Warren Hang, Hillsborough, NC (US); Ben Whittle, Bristol (GB); Richard John Sheffield Young, Somerset (GB)

(73) Assignee: E.I. DU PONT DE NEMOURS AND COMPANY, Wilmington, DE (US)

(21) Appl. No.: 12/905,375

(22) Filed: Oct. 15, 2010

Related U.S. Application Data
(60) Provisional application No. 61/253,585, filed on Oct. 21, 2009.

(51) Int. Cl. H01L 31/0224; H01L 31/18

(52) U.S. Cl. 136/256; 438/98; 257/E31.124

(57) ABSTRACT

A process for the production of a front-side electrode on a non-textured silicon wafer having an ARC layer on its front-side, wherein the front-side electrode is printed from a silver paste and fired, wherein the silver paste comprises (i) an inorganic content comprising (a) 93 to 95 wt.-% of electrically conductive metal powder comprising 90 to 100 wt.-% of silver powder, (b) 1 to 7 wt.-% of at least one glass frit, (c) 0 to 6 wt.-% of at least one solid inorganic oxide and (d) 0 to 6 wt.-% of at least one compound capable of forming a solid inorganic oxide on firing and (ii) an organic vehicle, wherein the weight ratio between the electrically conductive metal powder and the glass frit plus solid inorganic oxide is >13 to 19 in the fired state.

### FIELD OF THE INVENTION

The present invention is directed to a process of forming an electrode on the front-side of a non-textured silicon wafer.

### TECHNICAL BACKGROUND OF THE INVENTION

A conventional solar cell structure with a p-type base has a negative electrode that is typically on the front-side or illuminated side of the cell and a positive electrode on the back-side. It is well known that radiation of an appropriate wavelength falling on a p-n junction of a semiconductor body serves as a source of external energy to generate electron-hole pairs in that body. The potential difference that exists at a p-n junction, causes holes and electrons to move across the junction in opposite directions, thereby giving rise to flow of an electric current that is capable of delivering power to an external circuit. Most solar cells are in the form of a silicon wafer that has been metallized, i.e., provided with metal contacts which are electrically conductive.

Most electric power-generating solar cells currently used are silicon solar cells. Electrodes in particular are made by using a method such as screen printing from metal pastes.

The production of a p-type silicon solar cell typically starts with a p-type silicon substrate in the form of a silicon wafer on which an n-type diffusion layer of the reverse conductivity type is formed by the thermal diffusion of phosphorus (P) or the like. Phosphorus oxychloride (POCl₃) is commonly used as the gaseous phosphorus diffusion source, other liquid sources are phosphoric acid and the like. In the absence of any particular modification, the diffusion layer is formed over the entire surface of the silicon substrate. The p-n junction is formed where the concentration of the p-type dopant equals the concentration of the n-type dopant; conventional cells that have the p-n junction close to the illuminated side, have a junction depth between 0.05 and 0.5 μm.

After formation of this diffusion layer excess surface glass is removed from the rest of the surfaces by etching by an acid such as hydrofluoric acid.

Next, an ARC layer (antireflective coating layer) of, for example, TiOₓ, SiOₓ, TiOₓ/SiOₓ, or, in particular, SiNₓ or Si₃N₄ is formed on the n-type diffusion layer to a thickness of between 0.05 and 0.1 μm by a process, such as, for example, plasma CVD (chemical vapor deposition).

A conventional solar cell structure with a p-type base typically has a negative grid electrode on the front-side of the cell and a positive electrode on the back-side. The grid electrode is typically applied by screen printing and drying a front-side silver paste (front electrode forming silver paste) on the ARC layer on the front-side of the cell. The front-side grid electrode is typically screen printed in a so-called H pattern which comprises (i) thin parallel finger lines (collector lines) and (ii) two busbars intersecting the finger lines at right angle. In addition, a back-side silver or silver/aluminum paste and an aluminum paste are screen printed (or some other application method) and successively dried on the back-side of the substrate. Normally, the back-side silver or silver/aluminum paste is screen printed onto the silicon wafer's back-side first as two parallel busbars or as rectangles (tabs) ready for soldering interconnection strings (presoldered copper ribbons). The aluminum paste is then printed in the bare areas with a slight overlap over the back-side silver or silver/aluminum. In some cases, the silver or silver/aluminum paste is printed after the aluminum paste has been printed. Firing is then typically carried out in a belt furnace for a period of 1 to 5 minutes with the wafer reaching a peak temperature in the range of 700 to 900° C. The front grid cathode and the back anodes can be fired sequentially or cofired.

The aluminum paste is generally screen printed and dried on the back-side of the silicon wafer. The wafer is fired at a temperature above the melting point of aluminum to form an aluminum-silicon melt, subsequently, during the cooling phase, an epitaxially grown layer of silicon is formed that is doped with aluminum. This layer is generally called the back surface field (BSF) layer. The aluminum paste is transformed by firing from a dried state to an aluminum back anode. The back-side silver or silver/aluminum paste is fired at the same time, becoming a silver or silver/aluminum back anode. During firing, the boundary between the back-side aluminum and the back-side silver or silver/aluminum assumes an alloy state, and is connected electrically as well. The aluminum electrode accounts for most areas of the back electrode, owing in part to the need to form a p+ layer. A silver or silver/aluminum back electrode is formed over portions of the back-side (often as 2 to 6 mm wide busbars) as an electrode for interconnecting solar cells by means of pre-soldered copper ribbon or the like. In addition, the front-side silver paste printed as front-side grid electrode sinters and penetrates through the ARC layer during firing, and is thereby able to electrically contact the n-type layer. This type of process is generally called “firing through”.

Some silicon solar cell manufacturers work with non-textured silicon wafers. The latter can be made by forming the wafer directly from molten silicon. For example, this can be done by directly drawing a film of silicon at the desired thickness from a silicon melt, in particular, by pulling tungsten wires through a crucible of molten silicon at a controlled rate to produce a single long sheet or by pulling through an octagonal die to produce a hollow tube of silicon that is later separated into wafers. Silicon wafers fabricated in these ways have very smooth front and back surfaces.

In the description and the claims the term “non-textured silicon wafers” is used. It shall mean silicon wafers exhibiting an average surface roughness Rₐ in the range of 0.01 to 0.15 μm. Conventional silicon wafers (sawn silicon wafers made by cutting from a silicon ingot) have usually been textured using either an alkali process employing either NaOH or KOH and a wetting agent or an acid process employing a combination of HNO₃ and HF and they are distinguished by a higher average surface roughness Rₐ which is typically in the range of 0.5 to 1.7 μm. Whereas the non-textured silicon wafers and the conventional silicon wafers differ in average surface roughness Rₐ, they do not in terms of wafer size and wafer thickness; the silicon wafers have a thickness, typically in the range of 150 to 220 μm and a size, typically in the range of 100 to 250 cm².

In the description and the claims the term “average surface roughness Rₐ” is used. It means the average surface roughness Rₐ which is profilometrically determined according to ISO standard 4288:1996 (with lower cut-off filter set to 0.0025 mm and an upper cut-off of 0.8 mm with a bandwidth of 300:1). The profilometric measurement can be made with a conventional profilometer, for example, a Taylor Hobson Talysurf Ultra II profilometer equipped with a 2 μm diamond stylus at a sampling length of 4 mm with application of a Gaussian filter.

It has been found that the electrical efficiency of a silicon solar cell comprising a non-textured silicon wafer can be improved, where the silver paste used for the manufacture of the front-side electrode of the cell exhibits a certain ratio of silver powder, glass frit and, optionally, compounds selected from the group consisting of solid inorganic oxides and compounds capable of forming solid inorganic oxides during firing.

### SUMMARY OF THE INVENTION

The present invention relates to a process for the production of a front-side electrode of a silicon solar cell. Accordingly, it relates also to a process for the production of the silicon solar cell comprising said front-side electrode. The process comprises the steps:

1. providing a non-textured silicon wafer having an ARC layer on its front-side,

2. printing and drying a silver paste on the ARC layer on the front-side of the non-textured silicon wafer in a front-side electrode pattern, and

3. firing the printed and dried silver paste,

wherein the silver paste comprises (i) an inorganic content comprising (a) 93 to 95 wt.-% (weight-%) of electrically conductive metal powder comprising 90 to 100 wt.-% of silver powder, (b) 1 to 7 wt.-% of at least one glass frit, (c) 0 to 6 wt.-%, preferably 1 to 6 wt.-% of at least one solid inorganic oxide and (d) 0 to 6 wt.-% of at least one compound capable of forming a solid inorganic oxide on firing in step (3), and (ii) an organic vehicle,
wherein the weight ratio between the electrically conductive metal powder and the glass frit plus solid inorganic oxide is >13 to 19 in the fired state.

### DETAILED DESCRIPTION OF THE INVENTION

In step (1) of the process of the present invention a non-textured silicon wafer having an ARC layer on its front-side is provided. The non-textured silicon wafer is a mono- or polycrystalline silicon wafer as is conventionally used for the production of silicon solar cells; it has a p-type region, an n-type region and a p-n junction. The non-textured silicon wafer has an ARC layer, for example, of TiOₓ, SiOₓ, TiOₓ/SiOₓ, or, in particular, SiNₓ or Si₃N₄ on its front-side. Such silicon wafers are well known to the skilled person; for brevity reasons reference is made to the section “TECHNICAL BACKGROUND OF THE INVENTION”. The non-textured silicon wafer may already be provided with the conventional back-side metallizations, i.e. with a back-side aluminum paste and a back-side silver or back-side silver/aluminum paste as described above in the section “TECHNICAL BACKGROUND OF THE INVENTION”. Application of the back-side metal pastes may be carried out before or after the front-side cathode is finished. The back-side pastes may be individually fired or cofired or even be cofired with the front-side silver paste printed on the ARC layer in step (2) of the process of the present invention.

In step (2) of the process of the present invention a silver paste is printed on the ARC layer on the front-side of the non-textured silicon wafer. The silver paste is a thick film conductive composition which comprises an organic vehicle and an inorganic content comprising (a) 93 to 95 wt.-% of electrically conductive metal powder comprising 90 to 100 wt.-% of silver powder, (b) 1 to 7 wt.-% of at least one glass frit, (c) 0 to 6 wt.-%, preferably 1 to 6 wt.-% of at least one solid inorganic oxide and (d) 0 to 6 wt.-% of at least one compound capable of forming a solid inorganic oxide on firing in step (3) of the process of the present invention.

It is essential that the composition of the inorganic content of the silver paste is such that the weight ratio between the electrically conductive metal powder and the glass frit plus solid inorganic oxide is >13 to 19 in the fired state (after the firing in step (3) of the process of the present invention). Surprisingly, there is an optimum in electrical efficiency if said weight ratio is met. In case the inorganic content of the silver paste does not comprise any component (d), the weight ratio between the electrically conductive metal powder and the glass frit plus solid inorganic oxide in the fired state generally equals that of the silver paste used for printing in process step (2).

The silver paste comprises an organic vehicle. A wide variety of inert viscous materials can be used as organic vehicle. The organic vehicle may be one in which the particulate constituents (electrically conductive metal powder, glass frit, optionally present other particulate inorganic components) are dispersible with an adequate degree of stability. The properties, in particular, the rheological properties, of the organic vehicle may be such that they lend good application properties to the silver paste, including: stable dispersion of insoluble solids, appropriate viscosity and thixotropy for printing, in particular, for screen printing, appropriate wettability of the ARC layer on the front-side of the non-textured silicon wafer and of the paste solids, a good drying rate, and good firing properties. The organic vehicle used in the silver paste may be a nonaqueous inert liquid. The organic vehicle may be an organic solvent or an organic solvent mixture; in an embodiment, the organic vehicle may be a solution of organic polymer(s) in organic solvent(s). Use can be made of any of various organic vehicles, which may or may not contain thickeners, stabilizers and/or other common additives. In an embodiment, the polymer used as constituent of the organic vehicle may be ethyl cellulose. Other examples of polymers which may be used alone or in combination include ethylhydroxyethyl cellulose, wood rosin, phenolic resins and poly(meth)acrylates of lower alcohols. Examples of suitable organic solvents comprise ester alcohols and terpenes such as alpha- or beta-terpineol or mixtures thereof with other solvents such as kerosene, dibutylphthalate, diethylene glycol butyl ether, diethylene glycol butyl ether acetate, hexylene glycol and high boiling alcohols. In addition, volatile organic solvents for promoting rapid hardening after print application of the silver paste can be included in the organic vehicle. Various combinations of these and other solvents may be formulated to obtain the viscosity and volatility requirements desired.

The ratio of organic vehicle in the silver paste to the inorganic content (inorganic components; electrically conductive metal powder plus glass frit(s) plus optionally present solid inorganic oxide(s) plus optionally present compound(s) capable of forming a solid inorganic oxide plus optionally present other inorganic additives) is dependent on the method of printing the silver paste and the kind of organic vehicle used, and it can vary. Usually, the silver paste will contain 58 to 95 wt.-% of inorganic components and 5 to 42 wt.-% of organic vehicle.

The inorganic content of the silver paste comprises (a) 93 to 95 wt.-% of electrically conductive metal powder comprising 90 to 100 wt.-% of silver powder, (b) 1 to 7 wt.-% of at least one glass frit, (c) 0 to 6 wt.-%, preferably 1 to 6 wt.-% of at least one solid inorganic oxide and (d) 0 to 6 wt.-% of at least one compound capable of forming a solid inorganic oxide on firing in step (3) of the process of the present invention, wherein the weight ratio between the electrically conductive metal powder and the glass frit plus solid inorganic oxide is >13 to 19 in the fired state.

In an embodiment, the inorganic content of the silver paste consists of (a) 93 to 95 wt.-% of electrically conductive metal powder comprising 90 to 100 wt.-% of silver powder, (b) 1 to 7 wt.-% of at least one glass frit, (c) 0 to 6 wt.-%, preferably 1 to 6 wt.-% of at least one solid inorganic oxide and (d) 0 to 6 wt.-% of at least one compound capable of forming a solid inorganic oxide on firing in step (3) of the process of the present invention, wherein the weight ratio between the electrically conductive metal powder and the glass frit plus solid inorganic oxide is >13 to 19 in the fired state; here, the sum of the wt.-% of components (a) to (d) totals 100 wt.-%.

In a further embodiment, the inorganic content of the silver paste consists of (a) 93 to 95 wt.-% of electrically conductive metal powder comprising 90 to 100 wt.-% of silver powder, (b) 1 to 7 wt.-% of at least one glass frit and (c) 0 to 6 wt.-%, preferably 1 to 6 wt.-% of at least one solid inorganic oxide; here, the sum of the wt.-% of components (a) to (c) totals 100 wt.-%.

In an even further embodiment, the inorganic content of the silver paste consists of (a) 93 to 95 wt.-% of electrically conductive metal powder comprising 90 to 100 wt.-% of silver powder and (b) 5 to 7 wt.-% of at least one glass frit; here, the sum of the wt.-% of components (a) and (b) totals 100 wt.-%.

The silver paste comprises electrically conductive metal powder comprising 90 to 100 wt.-%, preferably 98 to 100 wt.-%, in particular 100 wt.-% of silver powder. In case the electrically conductive metal powder comprises one or more metal powders other than silver powder this or these are typically selected among copper powder, nickel powder and/or zinc powder. Preferably, the electrically conductive metal powder consists of silver powder. The electrically conductive metal powder or, in particular, silver powder may be uncoated or at least partially coated with a surfactant. The surfactant may be selected from, but is not limited to, stearic acid, palmitic acid, lauric acid, oleic acid, capric acid, myristic acid and linolic acid and salts thereof, for example, ammonium, sodium or potassium salts.

The average particle size of the electrically conductive metal powder or, in particular, silver powder is in the range of, for example, 0.5 to 5 μm. The total content of the electrically conductive metal powder or, in particular, silver powder in the silver paste is, for example, 55 to 90 wt.-%, or, in an embodiment, 65 to 85 wt.-%.

In the description and the claims the term “average particle size” is used. It means the mean particle diameter (d50) determined by means of laser scattering. All statements made in the present description and the claims in relation to average particle sizes relate to average particle sizes of the relevant materials as are present in the silver paste.

As already mentioned, the silver paste comprises at least one glass frit as inorganic binder. The average particle size of the glass frit is in the range of, for example, 0.5 to 4 μm.

The preparation of glass frit is well known and consists, for example, in melting together the constituents of the glass, predominantly in the form of the oxides of the constituents, and pouring such molten composition into water to form the frit. As is well known in the art, heating may be conducted to a peak temperature in the range of, for example, 1050 to 1250° C. and for a time such that the melt becomes entirely liquid and homogeneous, typically, 0.5-1.5 hours.

The glass may be milled in a ball mill with water or inert low viscosity, low boiling point organic liquid to reduce the particle size of the frit and to obtain a frit of substantially uniform size. It may then be settled in water or said organic liquid to separate fines and the supernatant fluid containing the fines may be removed. Other methods of classification may be used as well. One skilled in the art of producing glass frit may employ alternative synthesis techniques such as but not limited to water quenching, sol-gel, spray pyrolysis, or others appropriate for making powder forms of glass.

In an embodiment, the at least one glass frit is selected from the group consisting of glass frits containing 40 to 60 wt.-% of PbO, 5 to 15 wt.-% of PbF₂, 10 to 30 wt.-% of SiO₂, 0.1 to 5 wt.-% of Al₂O₃, 2 to 8 wt.-% of TiO₂, 0.3 to 10 wt.-% of Bi₂O₃ and 4 to 10 wt.-% of B₂O₃. As can be calculated from the weight percentages of PbO, PbF₂, SiO₂, Al₂O₃, TiO₂, Bi₂O₃ and B₂O₃, the latter do not necessarily add up to 100 wt.-%; however, in an embodiment, the total of the weight percentages of PbO, PbF₂, SiO₂, Al₂O₃, TiO₂, Bi₂O₃ and B₂O₃ is 100 wt.-%. In case the weight percentages of PbO, PbF₂, SiO₂, Al₂O₃, TiO₂, Bi₂O₃ and B₂O₃ do not total 100 wt.-%, the missing wt.-% may in particular be contributed by one or more other solid inorganic oxides.

In another embodiment, the at least one glass frit is selected from the group consisting of glass frits containing 44 to 65 wt.-% of PbO, 0.5 to 2.5 wt.-% of F, 10 to 30 wt.-% of SiO₂, 0.1 to 5 wt.-% of Al₂O₃, 2 to 8 wt.-% of TiO₂, 0.3 to 10 wt.-% of Bi₂O₃ and 4 to 10 wt.-% of B₂O₃; here, the fluorine content is expressed independent of its compound source. Examples of compounds serving as fluorine sources include PbF₂, BiF₃ and AlF₃. The weight percentages of PbO, the fluorine source(s), SiO₂, Al₂O₃, TiO₂, Bi₂O₃ and B₂O₃ do not necessarily add up to 100 wt.-%; however, in an embodiment, the total of the weight percentages of PbO, the fluorine source(s), SiO₂, Al₂O₃, TiO₂, Bi₂O₃ and B₂O₃ is 100 wt.-%. In case the weight percentages of PbO, the fluorine source(s), SiO₂, Al₂O₃, TiO₂, Bi₂O₃ and B₂O₃ do not total 100 wt.-%, the missing wt.-% may in particular be contributed by one or more other solid inorganic oxides.

The silver paste may comprise at least one solid inorganic oxide. Examples of solid inorganic oxides that can be used as components (c) of the inorganic content of the silver paste include silicon dioxide, magnesium oxide, lithium oxide and, in particular, zinc oxide.

The silver paste may comprise at least one compound capable of forming a solid inorganic oxide on firing of the printed and dried silver paste in step (3) of the process of the present invention. Examples of compounds that can be used as components (d) of the inorganic content of the silver paste comprise certain thermodecomposable inorganic compounds, namely inorganic compounds which decompose into solid inorganic oxide and gaseous decomposition products under the action of heat. Examples of such thermodecomposable inorganic compounds include metal hydroxides, metal carbonates and metal nitrates, for example, alkali metal carbonates and alkaline earth metal carbonates. Further examples of compounds that can be used as components (d) of the inorganic content of the silver paste comprise metal-organic compounds, i.e. metal-organic compounds are counted here as inorganic compounds and thus as belonging to the inorganic content of the silver paste. The term “metal-organic compounds” means metal compounds comprising at least one organic moiety in the molecule. The metal-organic compounds are stable or essentially stable, for example, in the presence of atmospheric oxygen or air humidity, under the conditions prevailing during preparation, storage and application of the silver paste. The same is true under the application conditions, in particular, under those conditions prevailing during printing of the silver paste onto the ARC layer on the front-side of the non-textured silicon wafer. However, during firing of the silver paste the organic portion of the metal-organic compounds will or will essentially be removed, for example, burned and/or carbonized. The metal-organic compounds may comprise covalent metal-organic compounds; in particular they comprise metal-organic salt compounds. Examples of suitable metal-organic salt compounds include in particular metal resinates (metal salts of acidic resins, in particular, resins with carboxyl groups) and metal carboxylates (metal carboxylic acid salts), such as, metal acetate, metal octoate, metal neodecanoate, metal oleate and metal stearate.

In an embodiment, the inorganic content of the silver paste is one consisting of (a) 93 to 95 wt.-% of electrically conductive metal powder comprising 98 to 100 wt.-%, preferably 100 wt.-% of silver powder, (b) 1 to 6 wt.-% of at least one glass frit selected from the group consisting of glass frits containing 40 to 60 wt.-% of PbO, 5 to 15 wt.-% of PbF₂, 10 to 30 wt.-% of SiO₂, 0.1 to 5 wt.-% of Al₂O₃, 2 to 8 wt.-% of TiO₂, 0.3 to 10 wt.-% of Bi₂O₃ and 4 to 10 wt.-% of B₂O₃, and (c) 1 to 6 wt.-% of zinc oxide; here, the sum of the wt.-% of components (a) to (c) totals 100 wt.-%.

In another embodiment, the inorganic content of the silver paste is one consisting of (a) 93 to 95 wt.-% of electrically conductive metal powder comprising 98 to 100 wt.-%, preferably 100 wt.-% of silver powder, (b) 1 to 6 wt.-% of at least one glass frit selected from the group consisting of glass frits containing 44 to 65 wt.-% of PbO, 0.5 to 2.5 wt.-% of F, 10 to 30 wt.-% of SiO₂, 0.1 to 5 wt.-% of Al₂O₃, 2 to 8 wt.-% of TiO₂, 0.3 to 10 wt.-% of Bi₂O₃ and 4 to 10 wt.-% of B₂O₃, and (c) 1 to 6 wt.-% of zinc oxide; here, the sum of the wt.-% of components (a) to (c) totals also 100 wt.-%, but the fluorine content is expressed independent of its compound source. Examples of compounds serving as fluorine sources include PbF₂, BiF₃ and AlF₃.

The silver paste is a viscous composition, which may be prepared by mechanically mixing the electrically conductive metal powder, the glass frit and the other optionally present solid inorganic components with the organic vehicle. In an embodiment, the manufacturing method power mixing, a dispersion technique that is equivalent to the traditional roll milling, may be used; roll milling or other mixing technique can also be used.

The silver paste can be used as such or may be diluted, for example, by the addition of additional organic solvent(s); accordingly, the weight percentage of all the other constituents of the silver paste may be decreased.

In step (2) of the process of the present invention the silver paste is printed, in particular, screen printed on the ARC layer on the front-side of the non-textured silicon wafer in a front-side electrode pattern, i.e. it is printed to form a front-side electrode. The front-side electrode may take the form of a grid pattern which comprises (i) thin parallel finger lines and (ii) two or more parallel busbars intersecting the finger lines at right angle. In an embodiment, the grid pattern is an H pattern with two parallel busbars. The parallel finger lines may have a distance between each other of, for example, 2 to 5 mm, a dry layer thickness of, for example, 3 to 30 μm and a width of, for example, 25 to 150 μm. The busbars may have a dry layer thickness of, for example, 10 to 50 μm and a width of, for example, 1 to 3 mm.

The printed silver paste is dried, for example, for a period of 1 to 100 minutes with the silicon wafer reaching a peak temperature in the range of 100 to 300° C. Drying can be carried out making use of, for example, belt, rotary or stationary driers, in particular, IR (infrared) belt driers.

In step (3) of the process of the present invention the printed and dried silver paste is fired. The firing of step (3) may be performed, for example, for a period of 1 to 5 minutes with the silicon wafer reaching a peak temperature in the range of 700 to 900° C. The firing can be carried out making use of, for example, single or multi-zone belt furnaces, in particular, multi-zone IR belt furnaces. The firing may happen in an inert gas atmosphere or in the presence of oxygen, for example, in the presence of air. During firing the organic substance including non-volatile organic material and the organic portion not evaporated during the drying may be removed, i.e. burned and/or carbonized, in particular, burned. The organic substance removed during firing includes organic solvent(s), optionally present organic polymer(s), optionally present organic additive(s) and the organic moieties of optionally present metal-organic compounds. Optionally present components (d) may decompose under formation of solid inorganic oxide during firing. There is a further process taking place during firing, namely sintering of the glass frit with the electrically conductive metal powder. The silver paste etches the ARC layer and fires through making electrical contact with the silicon substrate.

As already mentioned, firing may be performed as so-called cofiring together with back-side metal pastes that have been applied to the non-textured silicon wafer.

### EXAMPLES

### (1) Front-Side Silver Pastes

Example front-side silver pastes were made by conventional metal paste manufacturing techniques including mixing and roll-milling the paste constituents.

Comparative Paste 1 consisted of 81 wt.-% silver powder (average particle size 1.8 μm), 12 wt.-% organic vehicle (organic polymeric resins and organic solvents), 2 wt.-% glass frit and 5 wt.-% zinc oxide.

Example Paste 2 consisted of 82.8 wt.-% silver powder (average particle size 1.8 μm), 12 wt.-% organic vehicle (organic polymeric resins and organic solvents), 1.5 wt.-% glass frit and 3.7 wt.-% zinc oxide.

### (2) Manufacture of Solar Cells

Solar cells were formed as follows:

A 200 μm thick multicrystalline non-textured silicon wafer (area 243 cm², p-type (boron) bulk silicon, with an n-type diffused POCl₃ emitter, SiNₓ ARC layer on the wafer's emitter applied by CVD) was provided. The average surface roughness Rₐ of the wafer was 0.1172 μm; profilometrically determined according to ISO standard 4288:1996 (with lower cut-off filter set to 0.0025 mm and an upper cut-off of 0.8 mm with a bandwidth of 300:1). On its back surface the wafer was provided with a 30 μm thick aluminum electrode and two 5 mm wide busbars and overlapping with the aluminum film for 1 mm at both edges to ensure electrical continuity. On the front face of the wafer an example front-side silver paste was screen-printed and dried in an H pattern consisting of two 1.5 mm wide and 25 μm thick busbars at the edges of the wafer connected by 100 μm wide and 20 μm thick parallel finger lines having a distance of 2.2 mm between each other. All metal pastes were dried before cofiring.

The printed and dried wafers were fired in a Centrotherm 4-zone IR furnace. The set point of the spike firing zone (peak temperature encountered by the wafer) was between 875 and 950° C. After firing, the metallized wafers became functional photovoltaic devices.

Measurement of the electrical performance was undertaken. The solar cells formed according to the method described above were placed in a commercial I-V tester (supplied by h.a.l.m. elektronik GmbH) for the purpose of measuring light conversion efficiencies. The lamp in the I-V tester simulated sunlight of a known intensity (approximately 1000 W/m²) and illuminated the emitter of the cell. The metallizations on the cells were subsequently contacted by electrical probes. The photocurrent (Voc, open circuit voltage; Isc, short circuit current) generated by the solar cells was measured over a range of resistances to calculate the I-V response curve.

The electrical efficiency was calculated from the I-V curve.

Table 1 summarizes the results.

TABLE 1

| Silver | Peak temperature | Electrical efficiency |
|---|---|---|
| Paste | (° C.) | (%) |
| 1 | 875 | 8.98 |
| 1 | 900 | 10.86 |
| 1 | 925 | 10.2 |
| 2 | 875 | 12.34 |
| 2 | 900 | 12.49 |
| 2 | 925 | 11.86 |

What is claimed is:

1. A process for the production of a front-side electrode of a silicon solar cell comprising the steps:
1. providing a non-textured silicon wafer having an ARC layer on its front-side,
2. printing and drying a silver paste on the ARC layer on the front-side of the non-textured silicon wafer in a front-side electrode pattern, and
3. firing the printed and dried silver paste,
wherein the silver paste comprises (i) an inorganic content comprising (a) 93 to 95 wt.-% of electrically conductive metal powder comprising 90 to 100 wt.-% of silver powder, (b) 1 to 7 wt.-% of at least one glass frit, (c) 0 to 6 wt.-% of at least one solid inorganic oxide and (d) 0 to 6 wt.-% of at least one compound capable of forming a solid inorganic oxide on firing in step (3), and (ii) an organic vehicle,
wherein the weight ratio between the electrically conductive metal powder and the glass frit plus solid inorganic oxide is >13 to 19 in the fired state.

2. The process of claim 1, wherein the inorganic content of the silver paste consists of (a) 93 to 95 wt.-% of electrically conductive metal powder comprising 90 to 100 wt.-% of silver powder, (b) 1 to 7 wt.-% of at least one glass frit, (c) 0 to 6 wt.-% of at least one solid inorganic oxide and (d) 0 to 6 wt.-% of at least one compound capable of forming a solid inorganic oxide on firing in step (3), wherein the sum of the wt.-% of components (a) to (d) totals 100 wt.-%.

3. The process of claim 1, wherein the inorganic content of the silver paste consists of (a) 93 to 95 wt.-% of electrically conductive metal powder comprising 90 to 100 wt.-% of silver powder, (b) 1 to 7 wt.-% of at least one glass frit and (c) 0 to 6 wt.-% of at least one solid inorganic oxide, wherein the sum of the wt.-% of components (a) to (c) totals 100 wt.-%.

4. The process of claim 1, wherein the inorganic content of the silver paste consists of (a) 93 to 95 wt.-% of electrically conductive metal powder comprising 90 to 100 wt.-% of silver powder and (b) 5 to 7 wt.-% of at least one glass frit, wherein the sum of the wt.-% of components (a) and (b) totals 100 wt.-%.

5. The process of claim 1, wherein the at least one glass frit is selected from the group consisting of glass frits containing 40 to 60 wt.-% of PbO, 5 to 15 wt.-% of PbF₂, 10 to 30 wt.-% of SiO₂, 0.1 to 5 wt.-% of Al₂O₃, 2 to 8 wt.-% of TiO₂, 0.3 to 10 wt.-% of Bi₂O₃ and 4 to 10 wt.-% of B₂O₃.

6. The process of claim 1, wherein the at least one glass frit is selected from the group consisting of glass frits containing 44 to 65 wt.-% of PbO, 0.5 to 2.5 wt.-% of F, 10 to 30 wt.-% of SiO₂, 0.1 to 5 wt.-% of Al₂O₃, 2 to 8 wt.-% of TiO₂, 0.3 to 10 wt.-% of Bi₂O₃ and 4 to 10 wt.-% of B₂O₃.

7. The process of claim 1, wherein the inorganic content of the silver paste consists of (a) 93 to 95 wt.-% of electrically conductive metal powder comprising 98 to 100 wt.-% of silver powder, (b) 1 to 6 wt.-% of at least one glass frit selected from the group consisting of glass frits containing 40 to 60 wt.-% of PbO, 5 to 15 wt.-% of PbF₂, 10 to 30 wt.-% of SiO₂, 0.1 to 5 wt.-% of Al₂O₃, 2 to 8 wt.-% of TiO₂, 0.3 to 10 wt.-% of Bi₂O₃ and 4 to 10 wt.-% of B₂O₃, and (c) 1 to 6 wt.-% of zinc oxide, wherein the sum of the wt.-% of components (a) to (c) totals 100 wt.-%.

8. The process of claim 1, wherein the inorganic content of the silver paste consists of (a) 93 to 95 wt.-% of electrically conductive metal powder comprising 98 to 100 wt.-% of silver powder, (b) 1 to 6 wt.-% of at least one glass frit selected from the group consisting of glass frits containing 44 to 65 wt.-% of PbO, 0.5 to 2.5 wt.-% of F, 10 to 30 wt.-% of SiO₂, 0.1 to 5 wt.-% of Al₂O₃, 2 to 8 wt.-% of TiO₂, 0.3 to 10 wt.-% of Bi₂O₃ and 4 to 10 wt.-% of B₂O₃, and (c) 1 to 6 wt.-% of zinc oxide, wherein the sum of the wt.-% of components (a) to (c) totals 100 wt.-%.

9. The process of claim 1, wherein the electrically conductive metal powder is silver powder.

10. The process of claim 1, wherein the silver paste contains 58 to 95 wt.-% of inorganic components and 5 to 42 wt.-% of organic vehicle.

11. The process of claim 1, wherein the front-side electrode takes the form of a grid pattern which comprises (i) thin parallel finger lines and (ii) two or more parallel busbars intersecting the finger lines at right angle.

12. The process of claim 1, wherein the printing in step (2) is screen printing.

13. A front-side electrode produced according to the process of claim 1.

14. A silicon solar cell comprising a non-textured silicon wafer having an ARC layer on its front-side and a front-side electrode of claim 13.
